(19) United States
(12) Patent Application Publication
(10) Pub. No.: US 2026/0011595 A1
(43) Pub. Date: Jan. 8, 2026

(54) APPARATUS AND METHOD FOR THE ALIGNMENT OF A SUBSTRATE SUPPORT

(71) Applicant: Applied Materials, Inc., Santa Clara, CA (US)

(72) Inventors: Pinru LV, Wuxi (CN); Jianfeng FU, Hangzhou (CN); Ruixiang HUANG, Suzhou (CN)

(21) Appl. No.: 19/181,100

(22) Filed: Apr. 16, 2025

(30) Foreign Application Priority Data
May 22, 2024 (WO) PCT/CN2024/094753

(51) Int. Cl. H01L 21/68

(52) U.S. Cl. CPC H01L 21/68

(57) ABSTRACT

Disclosed herewith are an alignment apparatus and an alignment method for a susceptor of a processing chamber. The alignment apparatus includes a rotational module and a fitting module. The rotational module includes a bearing unit, a tubular member, and an attachment bracket. The attachment bracket is coupled to an end of the tubular member that is coupled to the bearing unit. The fitting module is coupled to the rotational module and includes a transparent plate configured to be disposed at a location above a susceptor of the processing chamber. The transparent plate includes plurality of first openings disposed along a first circular path and couples to a sensor that is configured to be positioned at a plurality of predetermined positions arranged along a second circular path that is concentric with the first circular path.

### CROSS REFERENCE TO RELATED APPLICATION

This application claims benefit of the PCT Application Serial No. PCT/CN2024/094753, filed May 22, 2024, all of which is incorporated herein by reference in its entirety.

### BACKGROUND

### Field

The present disclosure relates to an apparatus and method for aligning a substrate support of a processing chamber, and, more specifically, relates to an apparatus and method capable of aligning a substrate support with or without removing a transparent window of the processing chamber.

### Description of the Related Art

A semiconductor processing chamber, such as an epitaxy chamber, a rapid thermal processing chamber, or an etching chamber, often has a substrate supported and rotated by a susceptor to obtain uniform processing results. During processing, a substrate is rotated by the susceptor at a high rotational speed, such as a few hundreds of revolutions per minute (RPM). Thus, the susceptor needs to be precisely aligned with neighboring parts of the processing chamber to stay stable and avoid wobbling or collision.

Aligning a susceptor can be a time consuming process either during installation of a new chamber or during routine maintenance of the processing chamber. The traditional apparatus and method to align a susceptor often involve repeated opening and closing of a transparent dome that protects the susceptor, which is cumbersome and may cause other issues.

Thus, a need exists for an improved apparatus and method for aligning a susceptor of a processing chamber.

### SUMMARY

Disclosed herewith are an alignment apparatus and an alignment method for a substrate support of a processing chamber. In an example, the alignment apparatus includes a rotational module and a fitting module. The rotational module includes a bearing unit, a tubular member, and an attachment bracket. The attachment bracket is coupled to an end of the tubular member that is coupled to the bearing unit. The fitting module is coupled to the rotational module and includes a fitting plate having a plurality of first slots arranged along the circumference of a first circle having a first diameter.

In another example, the alignment apparatus includes a transparent plate configured to be disposed at a location above a substrate support of the processing chamber and comprising a plurality of first openings disposed along a first circular path. The alignment apparatus also includes a sensor coupled to the transparent plate and configured to be positioned at a plurality of predetermined positions arranged along a second circular path that is concentric with the first circular path.

In another example, the alignment method includes removing a transparent window protecting a substrate support from a supporting wall of the processing chamber, disposing a fitting ring on the supporting wall, disposing a fitting plate on the fitting ring, and attaching a measuring module to the fitting plate. The measuring module includes a laser module attached to a transparent plate. The alignment method further includes moving the laser module at a first location, measuring positional information of the substrate support and a neighboring part, and adjusting a position of the substrate support without removing the transparent plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 illustrates a schematic top view of a processing system, according to an embodiment of the present disclosure.

FIG. 2 illustrates a schematic cross-sectional view of a processing chamber, according to an embodiment of the present disclosure.

FIG. 3 illustrates a schematic top view of an alignment apparatus, according to an embodiment of the present disclosure.

FIG. 4 illustrates a schematic exploded view of a fitting module of an alignment apparatus, according to an embodiment of the present disclosure.

FIG. 5A illustrates a schematic side view of an attachment bracket of an alignment apparatus, according to an embodiment of the present disclosure.

FIG. 5B illustrates a schematic bottom view of an attachment bracket of an alignment apparatus, according to an embodiment of the present disclosure.

FIG. 6A illustrates a schematic placement of an alignment apparatus on top of an upper window, according to an embodiment of the present disclosure.

FIG. 6B illustrates a schematic placement of an alignment apparatus on a middle wall of a processing chamber, according to an embodiment of the present disclosure.

FIG. 7 illustrates a schematic perspective view of an alignment apparatus, according to an embodiment of the present disclosure.

FIG. 8 illustrates an adjustment operation via a slot of an alignment apparatus, according to an embodiment of the present disclosure.

FIG. 9 illustrates a method for aligning a substrate support in a processing chamber, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are an alignment apparatus and an alignment method for aligning a substrate support of a processing chamber. A substrate support is often protected by a transparent window, which can hinder the process for adjusting a position of the substrate support. The alignment apparatus as set forth in various embodiments of the present disclosure can be used with or without the transparent window, thus reducing the time in aligning the substrate support.

The alignment apparatus includes a fitting ring configured to be disposed on a supporting wall that is used for supporting the transparent window. A fitting plate, coupled with a measurement module, can be disposed within the fitting ring. The fitting plate includes a plurality of slots that allow a user to pass a tool through the fitting plate to adjust the substrate support without the need to remove the fitting plate. The alignment apparatus also includes a rotational module configured to move the measurement module to predetermined locations. A hold mechanism may use magnetic force to hold the measurement module in the predetermined locations.

The fitting plate may also have a shape that conforms to the transparent window. As a result, the fitting plate can be disposed directly on a top surface of the transparent window. Thus, the measurement of the positional information of the substrate support can also be implemented without removing the transparent window.

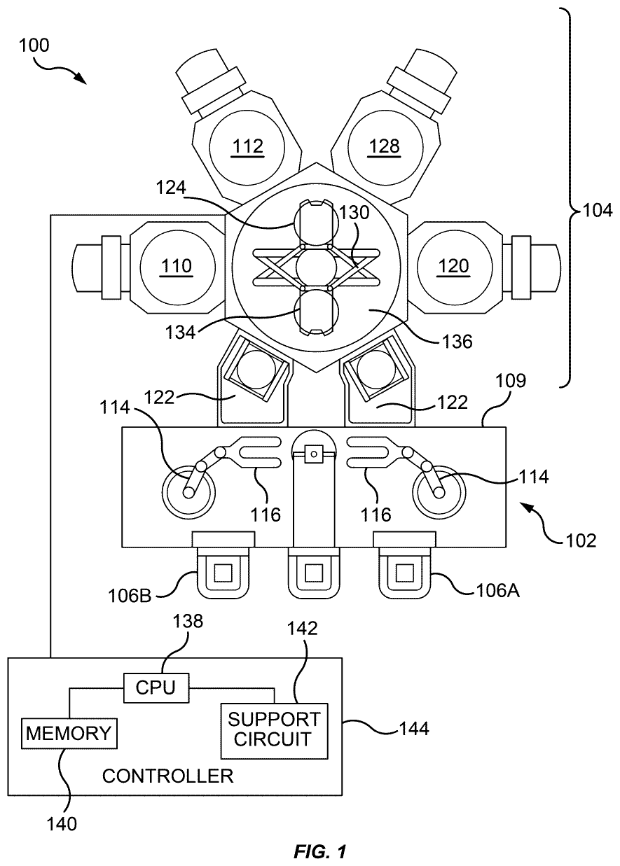

FIG. 1 illustrates a schematic top view of a processing system 100 for processing a substrate. The processing system 100 includes a processing platform 104 coupled with a factory interface 102 and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, one or more load lock chambers 122, and a transfer chamber 136 that is coupled to the one or more load lock chambers 122. The plurality of processing chambers 110, 112, 120, 128 may include a plasma enhanced chemical vapor deposition (PECVD) chamber, an epitaxy (EPI) chamber, a rapid thermal processing (RTP) chamber, a reactive ion etching (RIE) chamber, or other suitable chamber. The transfer chamber 136 can be maintained under vacuum, or can be maintained at an ambient (e.g., atmospheric) pressure. Two load lock chambers 122 are shown in FIG. 1. In an embodiment, any of the processing chambers 110, 112, 120, 128 includes a substrate support that supports and rotates a substrate. Precise alignment between the substrate support and neighboring parts is needed to obtain uniform processing results, such as thickness, smoothness, conductivity, dielectric constant, and other parameters of the processed substrate.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The factory interface 102 is coupled to the transfer chamber 136 through the load lock chambers 122. In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the factory interface robot 114 is configured to transfer one or more substrates from the FOUPS 106A, 106B, through the load lock chambers 122, to the processing platform 104 for processing. Substrates being transferred can be stored at least temporarily in the load lock chambers 122.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

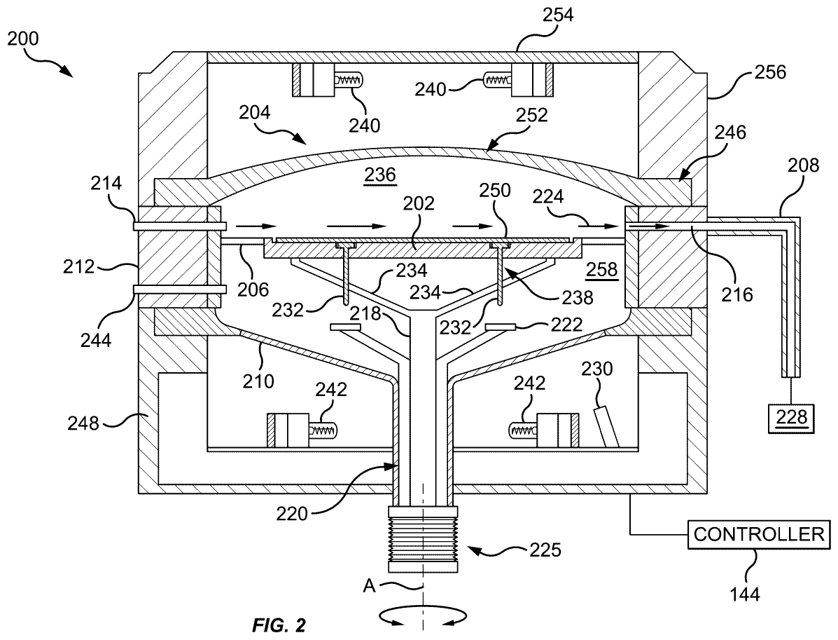

FIG. 2 illustrates a schematic cross-sectional view of a processing chamber 200 according to an embodiment. One or more of the processing chambers 110, 112, 128 shown in FIG. 1 can be configured as the processing chamber 200.

The processing chamber 200 includes an upper body 256, a lower body 248 disposed below the upper body 256, and a middle body 212 disposed between the upper body 256 and the lower body 248. Disposed within the chamber body is an upper window 204 (such as an upper dome), a lower window 210 (such as a lower dome), a plurality of upper heat sources 240, and a plurality of lower heat sources 242. A lid 254 is position above the upper window 204 and supports the upper heat source 240. The processing chamber 200 includes one or more thermal sensors 230 configured to detect a thermal condition of the processing chamber 200.

The upper window 204 is formed at least partially of an energy transmissive material, such as quartz, which allows the radiation emitted by the upper heat source 240 to pass through. The upper window 204 includes a base portion 246 and a central portion 252. The base portion 246 couples with the upper body 256 and the middle body 212 to secure the upper window 204. The central portion 252 may have a flat shape, a convex shape, or any other shape.

A substrate support 202 is disposed between the upper window 204 and the lower window 210. The substrate support 202 may include a susceptor, a pedestal, a chuck, or any other suitable supporting structure. An upper processing volume 236 is formed between the upper window 204 and the substrate support 202. A lower processing volume 258 is formed between the substrate support 202 and the lower window 210. An edge ring 206 neighboring the substrate support 202 is coupled to the middle body 212 and closes the gap between the substrate support 202 and the middle body 212. The edge ring 206 and the substrate support 202 need to be aligned according to manufacturer's specifications both during the initial installation and during a subsequent maintenance of the processing chamber. For example, the substrate support 202 and the edge ring 206 need to maintain an even separation gap to avoid contact. The heights of the substrate support 202 and the edge ring 206 also need to be maintained at substantially the same level.

The substrate support 202 supports the substrate 250 and is configured to rotate the substrate 250 during a process. The substrate support 202 is supported by an inner shaft 218 coupled with a motion assembly 226. The motion assembly 226 includes one or more actuators and/or adjustment devices that provide movement and/or adjustment for the inner shaft 218, which, in turn, moves the substrate support 202 and the substrate 250. The substrate support 202 is coupled to the inner shaft 218 through one or more arms 234. A plurality of lift pin holes 238 are disposed in the substrate support 202 and sized to accommodate a lift pin assembly 232 that is used to lift the substrate 250 from the substrate support 202. The lift pin assembly 232 is coupled with the motion assembly 226 via pedestals 222 of an outer shaft 220. In an embodiment, the position of the substrate support 202 needs to be examined and adjusted during routine maintenance to have a flat surface for supporting the substrate 250.

The middle body 212 includes a plurality of deposition gas inlets 214, a plurality of purge gas inlets 244, and one or more gas exhaust outlets 216. The gas exhaust outlets 216 are connected to an exhaust system 208 and an exhaust pump 228. A process gas 224 is provided by the deposition gas inlets 214. The exhaust system 208 is disposed on an opposite side of the processing chamber 200 relative to the middle body 212 and configured to pump out the effluent gases from the processing chamber 200.

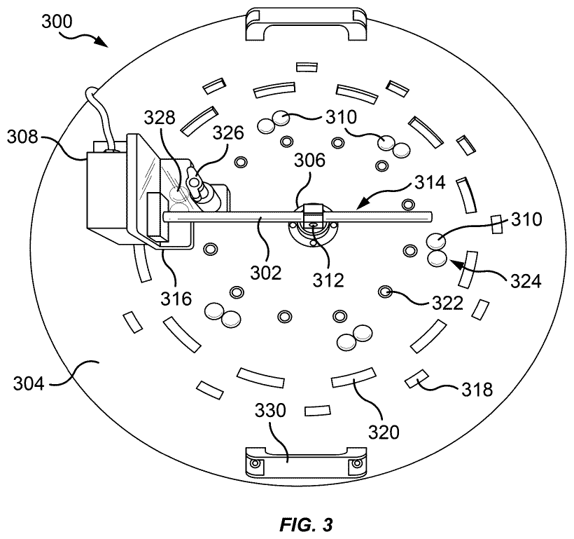

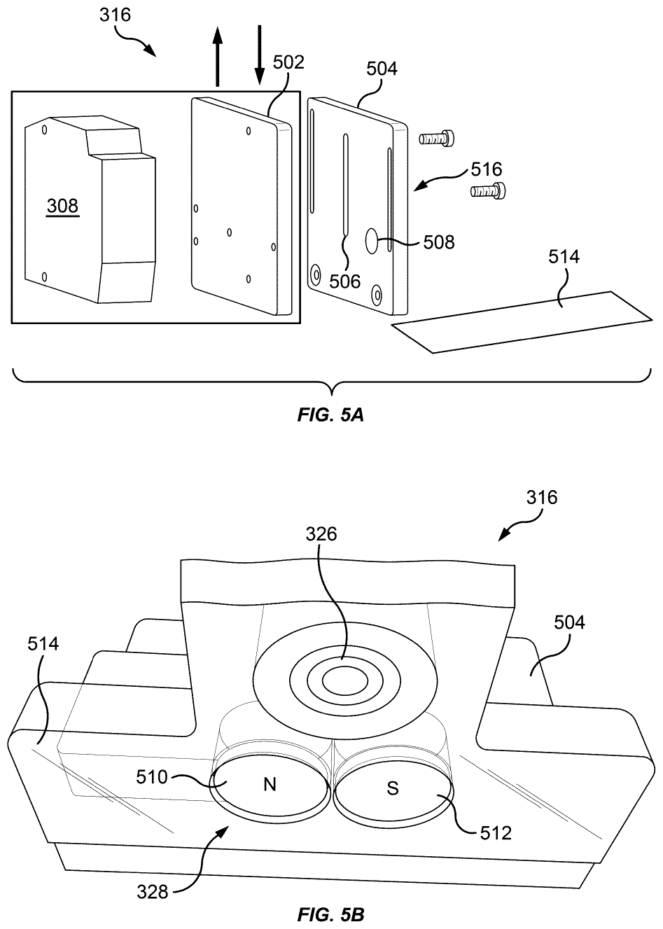

FIG. 3 illustrates a schematic top view of an alignment apparatus 300, according to an embodiment of the present disclosure. The alignment apparatus 300 is configured to measure the positional information of the edge ring 206 and the substrate support 202 (shown in FIG. 2). The positional information may include height difference and the size of a clearance gap between the substrate support 202 and the edge ring 206. Positional information with other neighboring parts may also be measured. The alignment apparatus 300 includes a rotational module 302 and a fitting module 304. The rotational module 302 is configured to rotate around a central axis 306 of the fitting module 304 and is capable of positioning a sensor 308 at a plurality of predetermined locations 310 on the surface of the fitting module 304. The predetermined locations 310 are arranged along a circular path, such as the circumference of the substrate support 202, such that the sensor 308 can measure the gap and height of the substrate support 202 and the edge ring 206. At the predetermined locations 310, a magnetic component 324 is disposed in a depression and is configured to hold the sensor 308 in place by pairing with another magnetic component 510 or 512 (shown in FIG. 5B) disposed in an attachment bracket 316. The sensor 308 may include a laser sensor configured to measure distance and height of an object.

The fitting module 304 is configured to position the rotational module 302 in the processing chamber, such as on the top of the upper window 204 or on the middle body 212. The fitting module 304 is made of a transmissive material, such as acrylic or quartz, so that an optical signal emitted by the laser sensor 308 can pass through the fitting module 304.

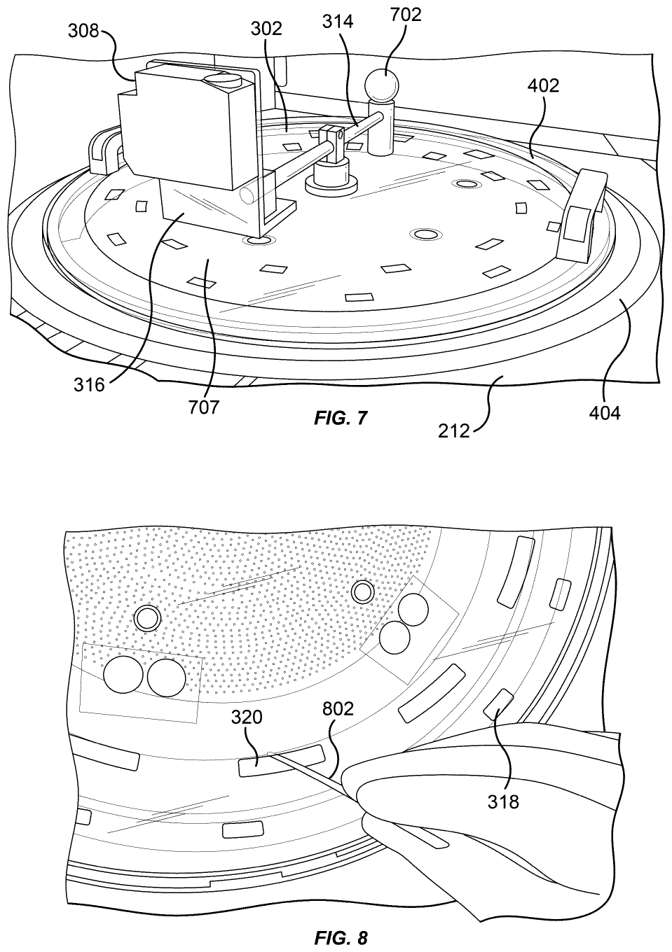

The rotational module 302 includes a bearing unit 312 coupled with a tubular member 314. The bearing unit 312 is aligned with the central axis 306 and is rotatable around the central axis 306. The tubular member 314 is substantially horizontal and is coupled with an attachment bracket 316 at one end. The sensor 308 is attached to the attachment bracket 316. A user can rotate the tubular member 314 around the bearing unit 312 to move the sensor 308 to different locations on the fitting module 304. In an embodiment, the tubular member 314 may have a counterbalance weight 702 (shown in FIG. 7) attached to another end.

The attachment bracket 316 is attached to the tubular member 314 and keeps a clearance gap from the surface of the fitting module 304 such that the attachment bracket 316 does not contact the fitting module 304. In an embodiment, the attachment bracket 316 has an L shape, with the vertical leg configured to attach the sensor 308 and the horizontal leg configured to include a holding mechanism 328 for holding the attachment bracket 315 at the predetermined locations 310. Details of the attachment bracket 316 will be provided later with references to other figures.

The fitting module 304 is configured to support the sensor 308 during measurement and adjustment of the substrate support 202. In an embodiment, the fitting module 304 may be disposed on the upper window 204 or the middle body 212 of the processing chamber 200. Thus, the fitting module 304 has a shape that conforms to the shape of the upper window 204 or the middle body 212.

The fitting module 304 includes a plurality of slots 318, 320 on the surface. For example, a plurality of first openings or slots 318 are arranged along a circular path, such as the circumference of a first circle sharing the same center as the substrate support 202. The first slots 318 allow a tool to pass through to adjust the positon of the edge ring 206. A plurality of second openings or slots 320 are arranged along another circular path, such as the circumference of a second circle. The second slots allow a tool to pass through to adjust the position of the substrate support 202. A plurality of openings or holes 322 are arranged along another circular path, such as the circumference of a third circle also having the same center as the substrate support 202. The holes 322 are parts of an optional locking mechanism 326 to lock the attachment bracket 316 at the predetermined locations 310. In an embodiment, the fitting module 304 also includes embedded magnetic components at predetermined locations 310 which are part of the holding mechanism 328. In an embodiment, the first circle, the second circle, and the third circle are concentric and share the common center axis 306. The fitting module 304 also includes two handles 330 for handling the alignment apparatus 300. The two handles 330 are dispose along an outer edge of the fitting module 304.

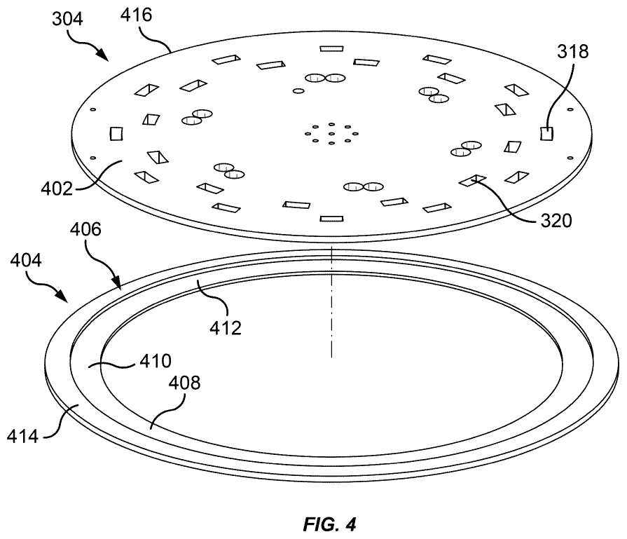

FIG. 4 illustrates a schematic exploded view of the fitting module 304, according to an embodiment of the present disclosure. The fitting module 304 includes a fitting plate 402 and a fitting ring 404. The fitting plate 402 has a shape that conforms to the upper window 204 and can be placed directly on the upper window 204. The fitting ring 404 has a shape that conforms to the middle body 212 and can be placed directed on the middle body 212. In an embodiment, when the upper window 204 is not removed during a measurement, the alignment apparatus 300 has the fitting plate 402 positioned directly on the upper window 204. In this embodiment, the fitting ring 404 may not be used. In another embodiment, when the upper window 204 is removed during a measurement, the alignment apparatus 300 has the fitting ring 404 placed on the middle body 212 and the fitting plate 402 placed on the fitting plate 402. In the latter configuration, a user not only can measure the positional information of the substrate support and the edge ring, but also can adjust the substrate support and the edge ring via the plurality of slots 318, 320 formed on the surface of the fitting plate 402.

In an embodiment, the fitting ring 404 is substantial annular. The fitting ring 404 has a shoulder portion 406 configured to fix the fitting plate 402 along a circumferential direction of the middle body 212. The fitting ring 404 has a flange portion 408 configured to support the fitting plate 402. The shoulder portion 406 has a top surface 414 that is higher than a top surface 410 of the flange portion 408. An inner circumference 412 of the shoulder portion 406 is about the same as an outer circumference 416 of the fitting plate 402 such that the fitting plate 402 can fit snugly within the fitting ring 404.

FIG. 5A illustrates a schematic side view of the attachment bracket 316, according to an embodiment of the present disclosure. The attachment bracket 316 is generally L-shaped with a vertical leg 516 and a horizontal leg 514. In an embodiment, the vertical leg 516 and the horizontal leg 514 are made of a transmissive material, such as quartz or acrylic.

The vertical leg 516 includes a first plate 502 coupled with a second plate 504, both of which are substantially vertical. The first plate 502 is configured to attach with the sensor 308. The second plate 504 is attached to the tubular member 314. A plurality of slots 506 are disposed in the second plate 504 through which fasteners, such as screws, may be disposed to fasten the second plate 504 to the first plate 502. The slots 506 allow the first plate 502 have an adjustable position along a vertical direction. As a result, the vertical position of the sensor 308 can be adjusted to position the sensor 308 within a measurable distance to the substrate support 202 and the edge ring 206. The second plate 504 also includes a depression 508 configured to couple with the tubular member 314.

FIG. 5B illustrates a schematic bottom view of the attachment bracket 316, according to an embodiment of the present disclosure. The horizontal leg includes a holding mechanism 328 and the locking mechanism 326. In an embodiment, the holding mechanism 328 includes a plurality of magnetic components 510 and 512 configured to generate an attracting force with the magnetic component 324 disposed in the depression at predetermined location 310. The magnetic components 510 and 512 may have reversed magnetic axes and may be embedded in the horizontal leg 514. The locking mechanism 326 may include a bolt configured to mate with a hole 322 to lock the attachment bracket 316 in a predetermined location 310.

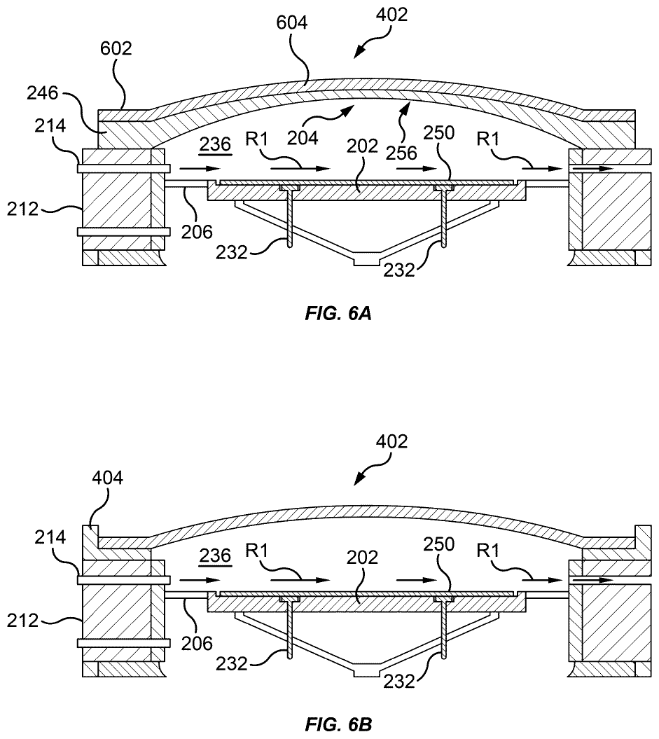

FIG. 6A illustrates a schematic side view of a fitting plate on the upper window, according to an embodiment of the present disclosure. The upper window 204 is supported by the middle body 212 and covers the processing volume 236. The fitting plate 402 is placed directly on the upper window 204. To be stably supported by the upper window 204, the fitting plate 402 may also have a base portion 602 that conforms to the base portion 246 of the upper window 204. The fitting plate 402 also has a central portion 604 that conforms to the central portion 252 of the upper window 204. The configuration shown in FIG. 6A may be used at the beginning of a maintenance cycle of a processing chamber or at the end of an installation of a processing chamber when the upper window 204 has already been installed in place.

FIG. 6B illustrates a schematic side view of a fitting module placed on a middle body 212, according to an embodiment of the present disclosure. The configuration in FIG. 6B is typically used when the substrate support 202 and the edge ring 206 need adjustment. In such a situation, the upper window 204 is removed to allow access to the substrate support 202 and the edge ring 206. The fitting ring 404 is disposed on the middle body 212, and the fitting plate 402 is disposed in the fitting ring 404. It is noted that the rotational module 302 and the sensor 308 are not shown in FIG. 6B.

FIG. 7 illustrates a schematic perspective view of an alignment apparatus placed on a middle body, according to an embodiment of the present disclosure. A counterbalance weight 702 is shown attached at an end of the tubular member 314, while the sensor 308 is attached at another end of the tubular member 314. Both the counterbalance weight 702 and the attachment bracket 316 maintain a clearance gap 704 with the surface of the fitting plate 402.

FIG. 8 illustrates a schematic operation for adjusting the edge ring or the substrate support, according to an embodiment of the present disclosure. As the upper window 204 is removed, a user can pass a tool 802 through a slot 320 to adjust the position of the edge ring or the substrate support. The user may also use the slot 318 for making adjustment.

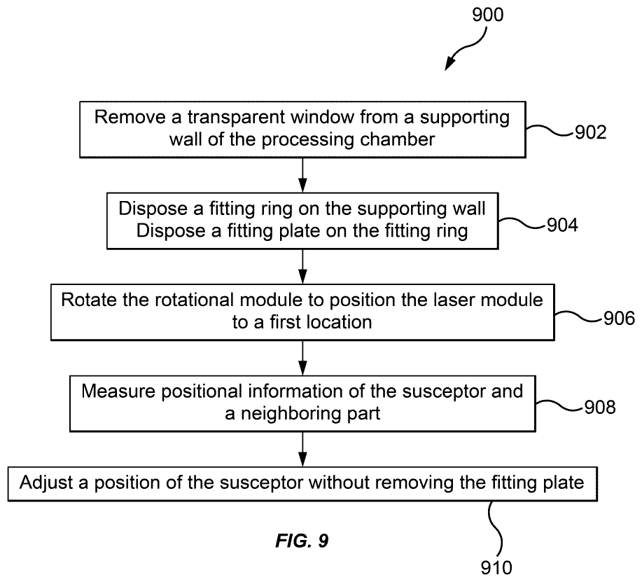

FIG. 9 illustrates a method for aligning a substrate support, according to an embodiment of the present disclosure. In an embodiment, the substrate support is a susceptor. The susceptor is disposed in a processing chamber and is protected by a transparent window, such as the upper window 204. The transparent window is disposed on a supporting wall, such as the middle body 212. An alignment apparatus that includes a rotational module and a fitting module is used for aligning the susceptor. The method 900 starts with an initial measurement of the positional information of the susceptor and neighboring parts, such as the edge ring. The fitting plate and the rotational module of the fitting module is placed directly on the transparent window for measurement.

At operation 902, the measurement shows that an alignment is required. Thus, the transparent window is removed to provide access to the susceptor.

At operation 904, the fitting ring is disposed on the supporting wall of the middle body. The fitting plate is then disposed in the fitting ring.

At operation 906, the rotational module is attached to the fitting plate, and the sensor is attached to the rotational module. The height of the sensor is adjusted vertically to keep the measurement distance within the specified distance of the sensor. Then, a user rotates the bearing unit to move the sensor to predetermined locations for measurement.

At operation 908, the sensor is held in the predetermined locations by the holding mechanism and the locking mechanism. The sensor measures positional information of the susceptor and neighboring parts, such as the edge ring.

At operation 910, a user passes a tool through the slots in the fitting plate to reach the susceptor and neighboring parts for adjustment. The operations from 906 to 910 may repeat until the susceptor is aligned according to the manufacturer's specifications. Then, the alignment apparatus is removed from the processing chamber, and the transparent window is reinstalled.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. An alignment apparatus for a processing chamber, comprising:
a transparent plate configured to be disposed at a location above a substrate support of the processing chamber and comprising a plurality of first openings disposed along a first circular path; and
a sensor coupled to the transparent plate and configured to be positioned at a plurality of predetermined positions arranged along a second circular path that is concentric with the first circular path.

2. The alignment apparatus of claim 1, further comprising a rotational module comprising a tubular member coupled to a bearing unit being attached to a center of the transparent plate, the sensor being coupled to an end of the tubular member.

3. The alignment apparatus of claim 2, wherein the rotational module further comprises an attachment bracket coupled to the end of the tubular member.

4. The alignment apparatus of claim 3, wherein the attachment bracket is separated from the transparent plate by a clearance gap.

5. The alignment apparatus of claim 3, wherein the attachment bracket comprises a plate having an adjustable vertical position, the sensor being attached to the plate of the attachment bracket.

6. The alignment apparatus of claim 3, wherein the rotational module comprises a counterbalance weight attached to another end of the tubular member.

7. The alignment apparatus of claim 3, wherein the transparent plate comprises a plurality of second openings arrange along a third circular path being concentric to the first circular path.

8. The alignment apparatus of claim 7, wherein the transparent plate further comprises a plurality of depressions arranged along a fourth circular path being concentric to the first circular path.

9. The alignment apparatus of claim 8, further comprising a first magnetic component disposed in one of the plurality of the depressions.

10. The alignment apparatus of claim 9, wherein the attachment bracket comprises a second magnetic component oriented to generate an attraction force with the first magnetic component.

11. The alignment apparatus of claim 10, wherein the attachment bracket further comprises a bolt.

12. The alignment apparatus of claim 1, wherein the transparent plate is made of quartz or acrylic.

13. The alignment apparatus of claim 1, wherein the sensor is a laser sensor configured to emit a laser beam toward the substrate support.

14. The alignment apparatus of claim 1, further comprising a fitting ring comprising a shoulder portion and a flange portion, a top surface of the shoulder portion being higher than a top surface of the flange portion.

15. The alignment apparatus of claim 14, wherein the shoulder portion has an inner circumference substantially equal to an outer circumference of the transparent plate.

16. A method for aligning a substrate support of a processing chamber, the method comprising:
removing a transparent window from a supporting wall of the processing chamber;
disposing a transparent plate at a location above the substrate support, the transparent plate being coupled with a sensor and comprising a plurality of openings arranged concentrically about a center of the transparent plate;
moving the sensor to a first location disposed along a circular path;
measuring positional information of the substrate support and a neighboring part with the sensor; and
adjusting a position of the substrate support or the neighboring part via one or more of the plurality of the openings.

17. The method of claim 16, further comprising:
disposing a fitting ring on the supporting wall; and
disposing the transparent plate in the fitting ring.

18. The method of claim 17, further comprising:
holding the sensor at the first location by a magnetic component disposed in the transparent plate; and
moving the sensor to a second location disposed along the circular path.

19. The method of claim 16, further comprising:
adjusting a height of the sensor.

20. The method of claim 19, further comprising:
disposing the transparent window on the supporting wall;
placing the transparent plate on the transparent window; and
measuring the positional information of the substrate support and the neighboring part with the sensor.
